(19) United States
(12) Patent Application Publication
(10) Pub. No.: US 2009/0051048 A1
(43) Pub. Date: Feb. 26, 2009

(54) Package structure and manufacturing method thereof

(75) Inventors: Yi-Shao Lai, Taipei County (TW); Tsung-Yueh Tsai, Kaohsiung (TW); Hsiao-Chuan Chang, Kaohsiung City (TW)

Correspondence Address: BACON & THOMAS, PLLC, 625 SLATERS LANE, FOURTH FLOOR, ALEXANDRIA, VA, 22314-1176, US

(73) Assignee: Advanced Semiconductor Engineering, Inc., Kaohsiung (TW)

(21) Appl. No.: 12/222,610

(22) Filed: Aug. 13, 2008

(30) Foreign Application Priority Data
Aug. 21, 2007 (TW) 96130959

(51) Int. Cl. H01L 21/60; H01L 23/48

(52) U.S. Cl. 257/778; 438/108; 257/E23.01; 257/E21.511

(57) ABSTRACT

A package structure and a manufacturing method thereof are provided. The package structure includes a carrier, a chip-bonding structure and a chip. The chip-bonding structure is formed on a first surface of the carrier. The chip-bonding structure includes a cavity, a dam, several via holes and several solder bumps. The solder bumps are received in the via holes and are correspond to the first connecting pads located on the carrier. The chip is embedded in the cavity of the chip-bonding structure. An active surface of the chip is tightly pasted on the first surface of the chip-bonding structure, and the first solder pads form electrical contact with the corresponding solder bumps. The chip of the package structure is precisely disposed on the carrier, not only simplifying the manufacturing process but also forming stable electrical connection between the chip and the carrier of the package structure.

This application claims the benefit of Taiwan application Serial No. 96130959, filed Aug. 21, 2007, the subject matter of which is incorporated herein by reference.

### BACKGROUND OF THE INVENTION

1. Field of the Invention

The invention relates in general to a package structure and the manufacturing method thereof, and more particularly to a new type of package structure which forms a chip bonding structure, into which the chip is embedded and precisely disposed, on the carrier and a manufacturing method thereof.

2. Description of the Related Art

The chip technology is continuously developed towards high frequency with large amount of contact pins, thus conventional wire bonding package cannot satisfy the needs of electrical characteristics. Flip-chip package uses tin-lead bumps to connect the chip with the substrate, not only largely increasing the pin density of the chip but also reducing the interference of noise, enhancing electrical efficiency, improving heat dissipation efficiancy and reducing package size. However, such flip-chip package still has numerous technical bottlenecks to be broken through. For example, to ensure that the chip and the substrate are tightly bound, the gap between the chip and the substrate is filled up by way of underfill dispensing. However, while dispensing the underfill, the flow direction of underfill is hard to control and may easily overflow and pollute the surface outside the underfill dispensing area on the substrate, affecting the subsequent process of wire bonding or the installation quality of other passive elements.

A semiconductor chip structure 200 which forms a flash-barrier on a substrate is disclosed in U.S. Pat. No. 6,400,036. As indicated in FIG. 1, the flash barrier 201 is disposed in the area between the chip receiving area 2021 and the solder pad 2022 of the substrate 202. Despite the flash barrier 201 of the conventional semiconductor chip structure 200 is capable of resolving the overflow of underfill, there are some other problems arise. Since the gap between the substrate 202 and the chip 203 is very small and the chip 203 has numerous pins, it is time-consuming to fill the gap between the substrate 202 and the chip 203 with the underfill 204 in the sealing process. Moreover, the underfill process has strict requirements on the viscosity and temperature of the underfill material. Even the thermo expansion coefficient of the underfill material needs to be taken into consideration, or the secureness of the electrical connection inside the semiconductor chip structure 200 will be jeopardized.

To resolve the above-described problem, a method of forming electrically conductive polymer interconnects on electrical substrates is disclosed in U.S. Pat. No. 6,138,348. As indicated in the FIG. 2, a conductive bump 3012 is formed on each first connecting pad 3011 of the first substrate 301. An organic passivation layer 303 is formed on one of the surfaces of the second substrate 302, and the second connecting pads 3021 of the second substrate 302 are respectively exposed in the via holes 3031 of the organic passivation layer 303. When the first substrate 301 is disposed on the second substrate 302, an electrical connection is formed between the first substrate 301 and the second substrate 302 via the mutual connections of the first connecting pads 3011, the conductive bumps 3012 and the second connecting pads 3021. Said method avoids forming a gap between the first substrate 301 and the second substrate 302 so as to resolve the difficulty of the sealing process. However, the method still requires the facilitation of an aligner bonder to make the first connecting pads 3011 and the conductive bumps 3012 disposed on the first substrate 301 align with the corresponding via holes 3031 and the second connecting pads 3021. However, the method of utilizing the aligner bonder to dispose the first substrate 301 on the second substrate 302 is rather complicated and is quite inconvenient to operate with. Still, there are some problems exist in the design of conventional package structure; hence having the nessesity to be further improved.

### SUMMARY OF THE INVENTION

The invention is directed to a package structure and a manufacturing method thereof, not only simplifying the manufacturing process but also improving electrical connection effect of the package structure.

According to a first aspect of the present invention, a package structure including a carrier, a chip-bonding structure and a chip is provided. The carrier has a first surface and a second surface opposite to the first surface. The first surface has a plurality of first connecting pads disposed thereon. The chip-bonding structure is disposed on the carrier and has a first surface and a second surface opposite to the first surface. The second surface of the chip-bonding structure is tightly pasted on the first surface of the carrier. The chip-bonding structure includes a cavity, a dam, several via holes and several solder bumps. The cavity is formed on the first surface of the chip-bonding structure, and the dam is disposed around the cavity. These via holes are disposed within the cavity and pass through the first surface and the second surface of the chip-bonding structure. The solder bumps are received in the via holes. The via holes and the corresponding solder bumps disposed therein are disposed on the first connecting pads of the carrier. The first connecting pads form electrical contact with the corresponding solder bumps. The chip has an active surface and a rear surface opposite to the active surface. Several first solder pads are disposed on the active surface. The chip is embedded in the cavity of the chip-bonding structure. The active surface of the chip is tightly pasted on the first surface of the chip-bonding structure. The first solder pads form electrical contact with the corresponding solder bumps.

According to a second aspect of the present invention, a manufacturing method of package structure is provided. The manufacturing method comprises the following steps:

Providing a carrier having a first surface and a second surface opposite to the first surface, several first connecting pads being formed on the first surface;

Forming a chip-bonding structure on the first surface of the carrier, the chip-bonding structure having a first surface and a second surface opposite to the first surface, the second surface of the chip-bonding structure being tightly pasted on the first surface of the carrier, the chip-bonding structure including a cavity formed on the first surface of the chip-bonding structure, a dam disposed around the cavity and several via holes disposed within the cavity and passing through the first surface and the second surface of the chip-bonding structure, the via holes being disposed on the first connecting pads of the carrier for exposing the first connecting pads;

Implanting several solder bumps into the via holes, the solder bumps being disposed on the first connecting pads of the carrier and forming electrical contact with the first connecting pads; and

Embedding a chip into the cavity of the chip-bonding structure, the chip having an active surface and a rear surface opposite to the active surface, several first solder pads being formed on the active surface, the active surface being tightly pasted on the first surface of the chip-bonding structure, the first solder pads forming electrical contact with the corresponding solder bumps.

Compared with the prior art, the chip of the package structure of the invention is embedded into the chip-bonding structure so as to be precisely disposed on the carrier, not only simplifying the manufacturing process but also forming stable electrical connection between the chip and the carrier of the package structure.

The invention will become apparent from the following detailed description of the preferred but non-limiting embodiment. The following description is made with reference to the accompanying drawings.

### BRIEF DESCRIPTION OF THE DRAWINGS

FIG. 1 (Prior Art) is a perspective of a conventional package structure.

FIG. 2 (Prior Art) is a perspective of another conventional package structure.

FIG. 3A is a perspective of a carrier of the invention.

FIG. 3B is a perspective showing a coating layer disposed on a first surface of the carrier according to the invention.

FIG. 3C is a perspective showing a chip-bonding structure being formed on the first surface of the carrier according to the invention.

FIG. 3D is a perspective showing several solder bumps being implanted into several via holes of a chip-bonding structure according to the invention.

FIG. 3E is a perspective showing a chip being embedded into a cavity of the chip-bonding structure according to the invention.

FIG. 3F is a perspective showing a molding compound being formed on the first surface of the carrier according to the invention.

FIG. 4 is a perspective showing a package structure of the invention.

FIG. 5 is a flowchart of a method of packaging package structure according to the invention.

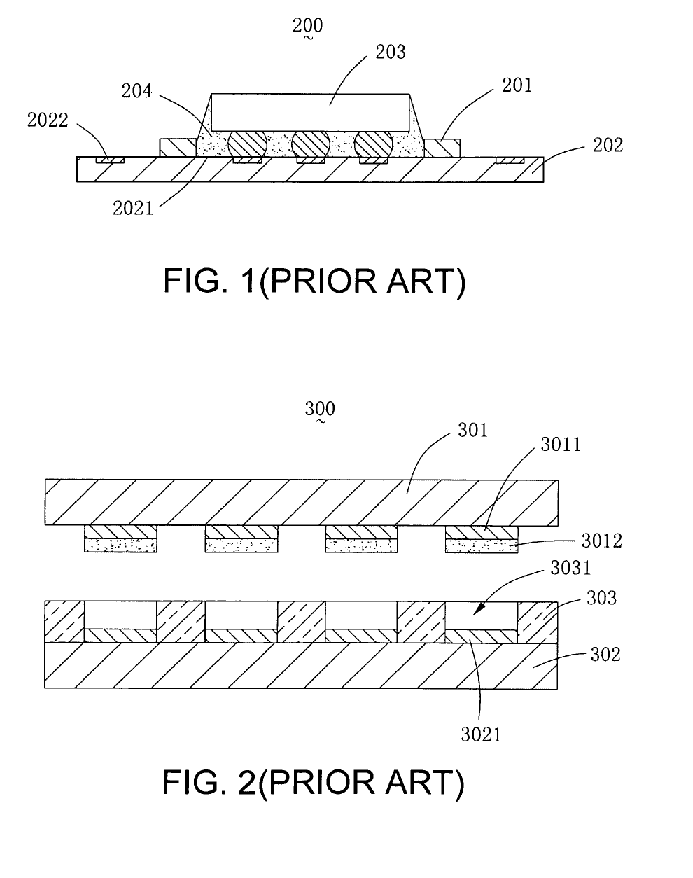

### DETAILED DESCRIPTION OF THE INVENTION

The details of a package structure and a manufacturing method thereof are elaborated in the present embodiment of the invention with accompanying drawings.

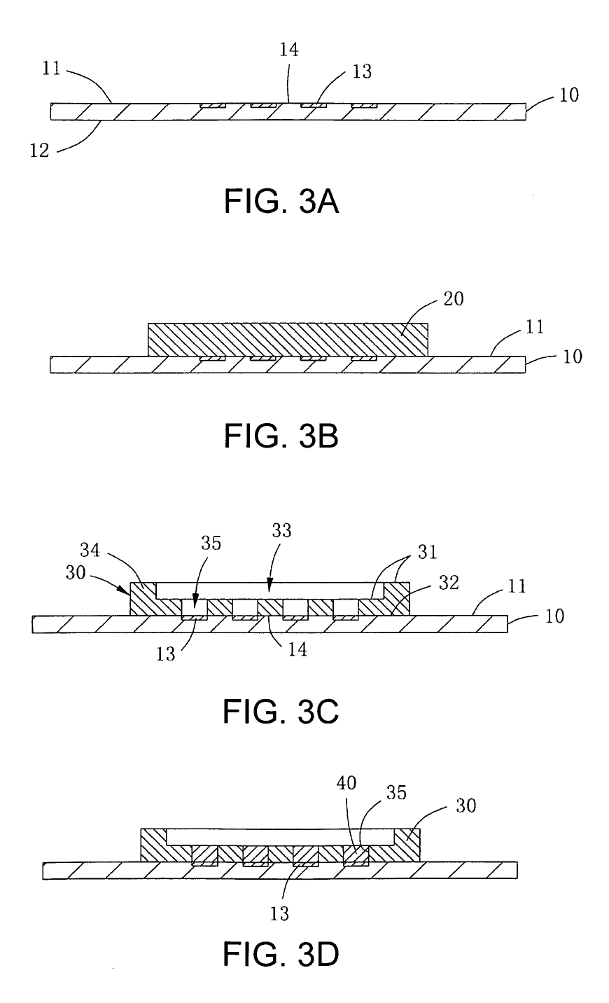

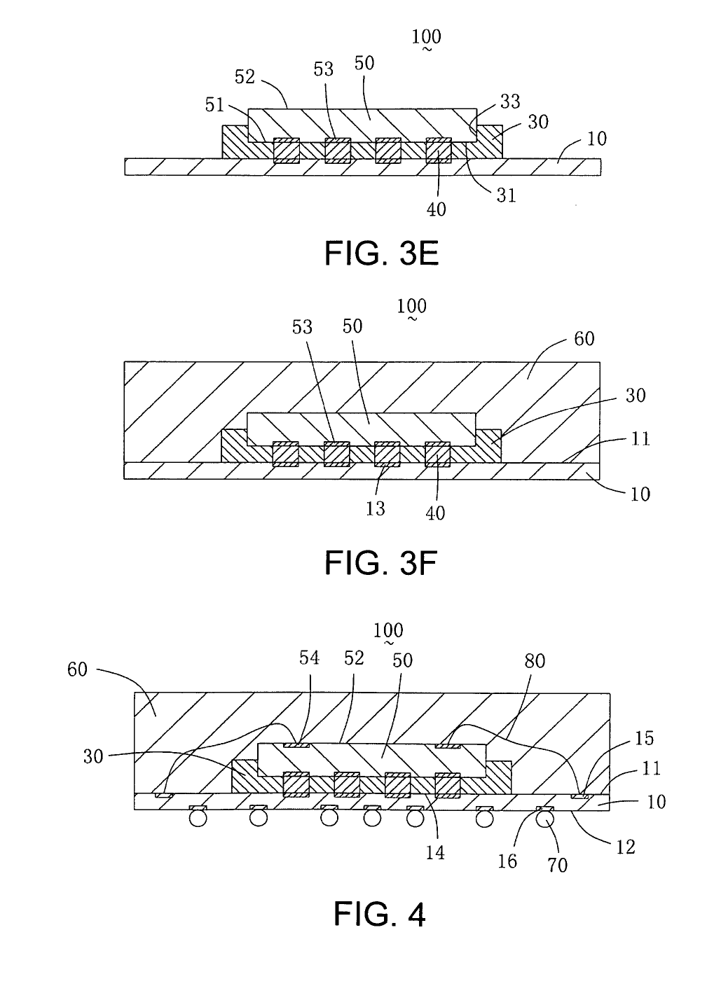

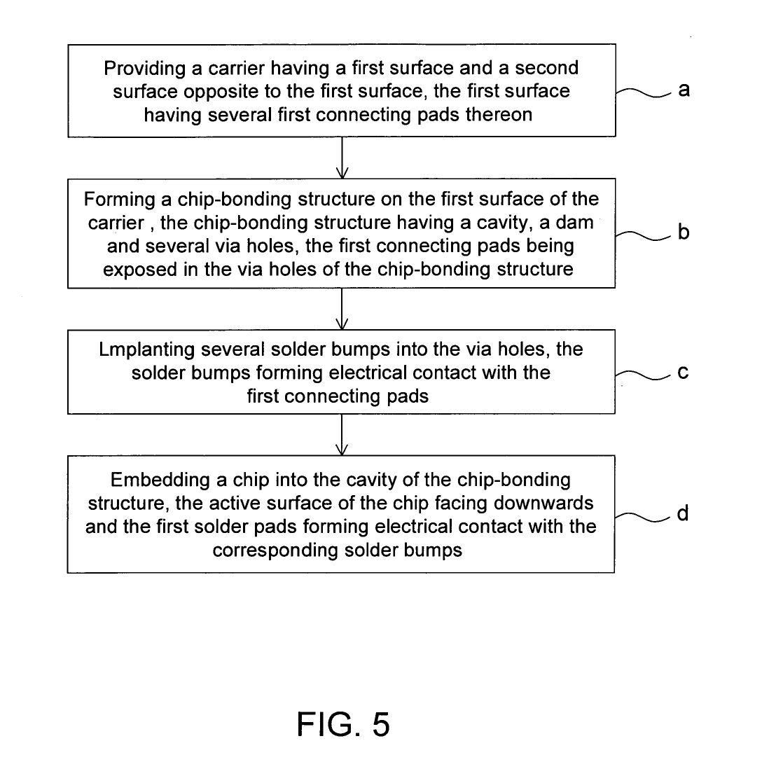

Referring to FIG. 3A and step a in FIG. 5, firstly, a carrier 10 having a first surface 11 and a second surface 12 opposite to the first surface 11 is provided. A chip receiving area 14 is formed on the first surface 11 and several first connecting pads 13 are formed on the chip receiving area 14.

Referring to FIG. 3B, a coating layer 20 is disposed on the first surface 11 of the carrier 10. In the present embodiment of the invention, the coating layer 20 is a solder mask.

Referring to FIG. 3C, the coating layer 20 is etched to form a chip-bonding structure 30 on the first surface 11 of the carrier 10. The chip-bonding structure 30 has a first surface 31 and a second surface 32 opposite to the first surface 31. The second surface 32 of the chip-bonding structure 30 is tightly pasted on the first surface 11 of the carrier 10. The chip-bonding structure 30 includes a cavity 33, a dam 34 and several of via holes 35. The cavity 33 is formed on the first surface 31 of the chip-bonding structure 30. In the present embodiment of the invention, the cavity 33 is disposed within the chip receiving area 14 of the carrier 10; and the dam 34 is disposed around the cavity 33 but outside the chip receiving area 14 of the carrier 10. The via holes 35 are disposed within the cavity 33 and pass through the first surface 31 and the second surface 32 of the chip-bonding structure 30. The via holes 35 are disposed on the first connecting pads 13 of the carrier 10 for exposing the first connecting pads 13.

In the present embodiment of the invention, the height of the dam 34 is smaller than that of the rear surface 52 of the chip 50 as indicated in FIG. 3E. Also, the height of the dam 34 can be equal to that of the rear surface 52 of the chip 50 as long as the chip 50 is embedded into the cavity 33.

The coating layer 20 can be etched by way of dry etching, wet etching or ion beam etching. The formation of the chip-bonding structure 30 of the invention is not limited to the way of etching the coating layer 20, and other methods would also be applicable. For example, the chip-bonding structure 30 is formed on the first surface 11 of the carrier 10 by way of molding, and other parts of the wafer structure 30, such as the cavity 33, a dam 34 and several via holes 35, can be formed concurrently or individually. The technology feature of the invention lies in the forming of the chip-bonding structure 30 on the first surface 11 of the carrier 10 as indicated in step b of FIG. 5, but not in the etching of the coating layer 20.

Referring to FIG. 3D and step c in FIG. 5, several solder bumps 40 are implanted into the via holes 35 of the chip-bonding structure 30. The solder bumps 40 are disposed on the first connecting pads 13 of the carrier 10 and form electrical contact with the first connecting pads 13.

Referring to FIG. 3E and step d in FIG. 5, a chip 50 having an active surface 51 and a rear surface 52 opposite to the active surface 51 is embedded into the cavity 33 of the chip-bonding structure 30. Several first solder pads 53 are formed on the active surface 51 of the chip 50. The active surface 51 is tightly pasted on the first surface 31 of the chip-bonding structure 30. The first solder pads 53 form electrical contact with the corresponding solder bumps 40.

A new type of package structure 100 is constituted according to the above-described manufacturing method. As indicated in FIG. 3E, the chip 50 of the package structure 100 is embedded into the chip-bonding structure 30 and disposed on the carrier 10, not only simplifying the manufacturing process, but also forming stable electrical connection between the chip 50 and the carrier 10.

Following the above-described step d, the manufacturing method of the package structure 100 can further perform a reflowing step of heating the first connecting pads 13, the solder bumps 40 and the first solder pads 53 such that these elements are bound together. Then, a molding compound 60 is formed on the first surface 11 of the carrier 10. As indicated in FIG. 3F, the molding compound 60 covers the chip 50, the chip-bonding structure 30 and the first surface 11 of the carrier 10.

Referring to FIG. 4, several second connecting pads 15 are further disposed on the first surface 11 of the carrier 10 of the package structure 100 of the invention, and the second connecting pads 15 are disposed outside the chip receiving area 14. Besides, several third connecting pads 16 are disposed on the second surface 12 of the carrier 10, and several solder balls 70 are implanted on the third connecting pads 16. Moreover, several second solder pads 54 can also be disposed on the rear surface 52 of the chip 50. With such arrangement of disposition, during packaging process, a wire bonding step can be performed prior to the molding step to form several bonding wires 80 between the chip 50 and the carrier 10 for connecting the second solder pads 54 of the chip 50 with the second connecting pads 15 of the carrier 10. Then, the sealing process is performed to from a molding compound 60 on the first surface 11 of the carrier 10. The molding compound 60 covers the chip 50, the chip-bonding structure 30, the first surface 11 of the carrier 10, the bonding wires 80, the second solder pads 54 of the chip 50 and the second connecting pads 15 of the carrier 10. Following the sealing process, the method may further comprise a step of solder ball implanting, so as to form several solder balls 70 on the third connecting pads 16 of the carrier 10.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A package structure, comprising:
a carrier having a first surface and a second surface opposite to the first surface, wherein the first surface has a plurality of first connecting pads disposed thereon;
a chip-bonding structure disposed on the carrier, wherein the chip-bonding structure has a first surface and a second surface opposite to the first surface, the second surface of the chip-bonding structure is tightly pasted on the first surface of the carrier, and the chip-bonding structure comprises:
a cavity formed on the first surface of the chip-bonding structure;
a dam disposed around the cavity;
a plurality of via holes disposed within the cavity and passing through the first surface and the second surface of the chip-bonding structure; and
a plurality of solder bumps received in the via holes;
wherein the via holes and the corresponding solder bumps therein are disposed on the first connecting pads of the carrier, and the first connecting pads form electrical contact with the corresponding solder bumps; and
a chip having an active surface and a rear surface opposite to the active surface, wherein the active surface has a plurality of first solder pads disposed thereon, the chip is embedded in the cavity of the chip-bonding structure, the active surface of the chip is tightly pasted on the first surface of the chip-bonding structure, and the first solder pads form electrical contact with the corresponding solder bumps.

2. The package structure according to claim 1, further comprising a molding compound disposed on the first surface of the carrier and covering the chip, the chip-bonding structure and the first surface of the carrier.

3. The package structure according to claim 1, wherein the height of the dam of the chip-bonding structure is smaller than or equal to that of the rear surface of the chip.

4. The package structure according to claim 1, wherein a chip receiving area is formed on the first surface of the carrier, and the first connecting pads is formed within the chip receiving area.

5. The package structure according to claim 4, wherein the dam of the chip-bonding structure is disposed outside the chip receiving area, and the cavity of the chip-bonding structure is disposed within the chip receiving area.

6. The package structure according to claim 4, wherein the first surface of the carrier further has a plurality of second connecting pads disposed thereon, and the second connecting pads are disposed outside the chip receiving area.

7. The package structure according to claim 6, wherein the rear surface of the chip further has a plurality of second solder pads disposed thereon, and the second solder pads of the chip are connected to the second connecting pads of the carrier via a plurality of bonding wires.

8. The package structure according to claim 7, further comprising a molding compound covering the chip, the chip-bonding structure, the first surface of the carrier, the bonding wires, the second solder pads of the chip and the second connecting pads of the carrier.

9. The package structure according to claim 2, wherein the second surface of the carrier has a plurality of third connecting pads disposed thereon, and a plurality of solder balls are disposed on the third connecting pads.

10. The package structure according to claim 8, wherein the second surface of the carrier has a plurality of third connecting pads disposed thereon, and a plurality of solder balls are disposed on the third connecting pads.

11. A manufacturing method of package structure, comprising the following steps:
providing a carrier having a first surface and a second surface opposite to the first surface, wherein the first surface has a plurality of first connecting pads disposed thereon;
forming a chip-bonding structure on the first surface of the carrier, wherein the chip-bonding structure has a first surface and a second surface opposite to the first surface, the second surface of the chip-bonding structure is tightly pasted on the first surface of the carrier, the chip-bonding structure comprises a cavity formed on the first surface of the chip-bonding structure, a dam disposed around the cavity and a plurality of via holes disposed within the cavity and passing through the first surface and the second surface of the chip-bonding structure, and the via holes are disposed on the first connecting pads of the carrier for exposing the first connecting pads;
implanting a plurality of solder bumps into the via holes, wherein the solder bumps are disposed on the first connecting pads of the carrier and form electrical contact with the first connecting pads; and
embedding a chip into the cavity of the chip-bonding structure, wherein the chip has an active surface and a rear surface opposite to the active surface, a plurality of first solder pads are formed on the active surface, the active surface is tightly pasted on the first surface of the chip-bonding structure, and the first solder pads form electrical contact with the corresponding solder bumps.

12. The manufacturing method of package structure according to claim 11, further comprising forming a molding compound on the first surface of the carrier to cover the chip, the chip-bonding structure and the first surface of the carrier.

13. The manufacturing method of package structure according to claim 11, wherein the height of the dam of the chip-bonding structure is smaller than or equal to that of the rear surface of the chip.

14. The manufacturing method of package structure according to claim 11, wherein the step of forming the chip-bonding structure comprises disposing a coating layer on the first surface of the carrier and etching the coating layer to form the chip-bonding structure;
wherein after the step of embedding the chip into the cavity of the chip-bonding structure, the method further comprises a reflowing step of heating the first connecting pads, the solder bumps and the first solder pads such that elements are bound together.

15. The manufacturing method of package structure according to claim 11, wherein a chip receiving area is formed on the first surface of the carrier, and the first connecting pads are formed within the chip receiving area, and the dam of the chip-bonding structure is disposed outside the chip receiving area, and the cavity of the chip-bonding structure is disposed within the chip receiving area.

16. The manufacturing method of package structure according to claim 14, wherein the first surface of the carrier has a plurality of second connecting pads disposed thereon, and the second connecting pads are disposed outside the chip receiving area.

17. The manufacturing method of package structure according to claim 16, wherein the rear surface of the chip has a plurality of second solder pads disposed thereon, and the method further comprises a wire bonding step of forming a plurality of bonding wires between the chip and the carrier for connecting the second solder pads of the chip with the second connecting pads of the carrier.

18. The manufacturing method of package structure according to claim 17, further comprising forming a molding compound on the first surface of the carrier to cover the chip, the chip-bonding structure, the first surface of the carrier, the bonding wires, the second solder pads of the chip and the second connecting pads of the carrier.

19. The manufacturing method of package structure according to claim 12, wherein the second surface of the carrier has a plurality of third connecting pads disposed thereon and the method further comprises a solder ball implanting step of forming a plurality of solder balls on the third connecting pads of the carrier.

20. The manufacturing method of package structure according to claim 18, wherein the second surface of the carrier has a plurality of third connecting pads disposed thereon and the method further comprises a solder ball implanting step of forming a plurality of solder balls on the third connecting pads of the carrier.
